(19) United States
(12) Patent Application Publication
(10) Pub. No.: US 2026/0122787 A1
(43) Pub. Date: Apr. 30, 2026

(54) PRESSURE SENSOR AND METHOD OF MANUFACTURING THE SAME

(71) Applicants: QingDing Precision Electronics (Huai’an) Co., Ltd., Jiangsu Province (CN); Avary Holding (Shenzhen) Co., Ltd., Shenzhen (CN); Garuda Technology Co., Ltd., New Taipei City (TW)

(72) Inventors: Hsiao-Ting HSU, Shenzhen (CN); Chiawei CHANG, Shenzhen (CN); Ming-Jaan HO, Shenzhen (CN)

(21) Appl. No.: 18/931,790

(22) Filed: Oct. 30, 2024

(51) Int. Cl. H05K 1/18; G01L 1/16; H05K 1/14; H05K 3/00; H05K 3/46

(52) U.S. Cl. CPC H05K 1/189; G01L 1/16; H05K 1/147; H05K 1/184; H05K 1/185; H05K 3/0044; H05K 3/4644; H05K 3/4697; H05K 2201/0133; H05K 2201/10083

(57) ABSTRACT

A pressure sensor and method of manufacturing the same are provided. The pressure sensor includes a flexible sensor board. The flexible sensor board includes a dielectric layer, two circuit layers and piezoelectric sensing blocks. The dielectric layer has a first surface and a second surface opposite to the first surface. The two circuit layers are placed on the first surface and the second surface of the dielectric layer respectively. The piezoelectric sensing blocks are placed in dielectric layer and electrically connected with the two circuit layers. The mentioned pressure sensor utilizes the flexible sensor board that can be suitable for to the curvature of the diffident curved surfaces of the tested sample, which helps to improve the consistency and accuracy of the measurements.

### BACKGROUND

### Field of Invention

The present disclosure relates the field of sensor technology, and in particular to a pressure sensor and a manufacturing method thereof.

### Description of Related Art

Pressure sensors are widely applied in the field of consumer electronics, automotive electronics, industrial electronics, wearable electronics, Human-Computer Interaction (HCl), biomedical electronics and health monitoring. Generally, pressure sensors are usually disposed on the surface of an object. However, existing pressure sensors are often affected by uneven surface of the object (for example, a curved or irregular surface), thereby causing the accuracy of the pressure sensor measurements to worsen.

### SUMMARY

At least one embodiment of the present disclosure provides a pressure sensor which improves the accuracy of the measurements.

At least one embodiment of the present disclosure provides a method of manufacturing of the pressure sensor.

At least one embodiment of the present disclosure provides a pressure sensor including a flexible sensor board. The flexible sensor board includes a dielectric layer, two circuit layers and a plurality of piezoelectric sensing blocks. The dielectric layer has a first surface and a second surface opposite to the first surface. The two circuit layers are placed on the first surface and the second surface of the dielectric layer respectively. These piezoelectric sensing blocks are placed in dielectric layer and electrically connected with the two circuit layers.

At least one embodiment of the present disclosure provides a method of manufacturing the pressure sensor including providing a dielectric layer which has a first surface and a second surface opposite to the first surface. Two circuit layers are placed on the first surface and the second surface of the dielectric layer respectively. A plurality of piezoelectric sensing blocks is placed in dielectric layer. These piezoelectric sensing blocks electrically connect with the two circuit layers.

According to the above description, the pressure sensor disclosed in the above embodiment of the present disclosure is not only suitable for the diffident surfaces of tested samples, for example, a curved surface, but also distributing strain evenly to improve measurement accuracy by using the abovementioned flexible sensor board.

### BRIEF DESCRIPTION OF THE DRAWINGS

The disclosure can be more fully understood by reading the following detailed description of the embodiment, with reference made to the accompanying drawings as follows:

FIG. 1 illustrates a cross-section schematic diagram of a pressure sensor bending according to at least one embodiment of the present disclosure.

FIG. 2 illustrates a cross-section schematic diagram of a pressure sensor bending according to another embodiment of the present disclosure.

FIG. 3A to FIG. 3B illustrate cross-section schematic diagrams of the pressure sensor measuring the tested sample according to FIG. 1 and FIG. 2.

FIG. 4A is a plot of time versus deformation of the flexible sensor board according to FIG. 3A and FIG. 3B.

FIG. 4B is a plot of time versus deformation of the piezoelectric sensing blocks according to FIG. 3B.

FIG. 5A to FIG. 5D illustrate cross-section schematic diagrams of a method of manufacturing the pressure sensor of at least one embodiment of the present disclosure.

FIG. 6A to FIG. 6B illustrate cross-section schematic diagrams continuing the method of manufacturing of FIG. 5A to FIG. 5D.

FIG. 7A to FIG. 7B illustrate cross-section schematic diagrams continuing the method of manufacturing of FIG. 5A to FIG. 5D.

FIG. 8A to FIG. 8B illustrate cross-section schematic diagrams of a method of manufacturing the pressure sensor of at least one embodiment of the present disclosure.

FIG. 9 illustrates cross-section schematic diagrams of a method of manufacturing the pressure sensor of at least one embodiment of the present disclosure.

### DETAILED DESCRIPTION

In the following text, in order to clearly present the technical features of this case, the dimensions (such as length, width, thickness and depth) of the components (such as layers, electrodes, base boards, regions, etc.) in the drawings are expressed in unequal proportions to be enlarged, and the number of some components will be reduced. Therefore, the description and explanation of the embodiments below are not limited to the number of components and the sizes and shapes of the components in the drawings, but should cover the size, shape, and deviations in both caused by actual manufacturing processes and/or tolerances. For example, regions shown or described as flat may typically have rough and/or non-linear characteristics. Additionally, the acute angles shown may be rounded. Therefore, the components shown in the drawings of this case are mainly for illustration, and are not intended to accurately depict the actual shapes of the components, nor are they intended to limit the patent scope of this case.

Secondly, words such as “about”, “approximate”, or “substantially” as they appear in this case cover not only clearly stated values and ranges of values, but also permissible range of deviation as understood by a person having ordinary skill in the art (PHOSITA) or in the field to which the disclosure belongs, where such ranges of deviation may be determined by the error in measurement, which may arise, for example, from limitations of either the measurement system or the process conditions. In addition, “about” may be expressed within one or more standard deviations of the above values, such as ±30%, ±20%, ±10%, or ±5%. Words such as “about”, “approximately”, or “substantially” in this text of this case can be used to select an acceptable range of deviation or standard deviation based on optical, etching, mechanical, or other properties, rather than applying a single standard deviation to all of the above properties, such as optical, etching, mechanical, and other properties.

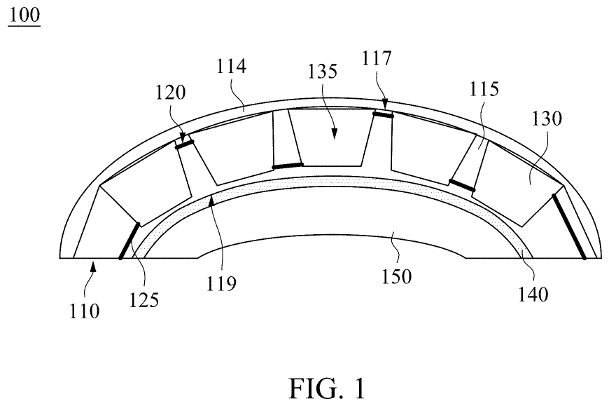

FIG. 1 is a cross-section schematic diagram of a pressure sensor 100 bending according to at least one embodiment of the present disclosure. Referring to FIG. 1, the pressure sensor 100 includes a flexible sensor board 110. The flexible sensor board 110 includes a dielectric layer 115, two circuit layers 120 and a plurality of piezoelectric sensing blocks 130. The dielectric layer 115 has a first surface 117 and a second surface 119 opposite to the first surface 117. The first surface 117 can be an outer convex surface or an inner concave surface. In the same way, the second surface 119 opposite to the first surface 117 can also be a convex surface or a concave surface. The two circuit layers 120 are placed on the first surface 117 and the second surface 119 of the dielectric layer 115 respectively. These piezoelectric sensing blocks 130 are placed in the dielectric layer 115 and electrically connected with the two circuit layers 120. For example, these piezoelectric sensing blocks 130 directly contacts and connects to the circuit layers 120.

The circuit layers 120 each include traces 125, and at least one of the traces 125 electrically connects to two of these piezoelectric sensing blocks 130. The pressure sensor 100 also includes a cover layer 114, a support board 150 and an adhesive layer 140. The cover layer 114 covers the circuit layers 120 to protect the traces 125 of the circuit layers 120. The support board 150 has a curved surface (not labeled) that covers the second surface 119 of the flexible sensor board 110. The adhesive layer 140 is attached between the flexible sensor board 110 and the support board 150.

The flexible sensor board 110 is flexible and can be bent. For example, the flexible sensor board 110 can be bent into a U-shape, and the dielectric layer 115 thereof can be a sheet having elasticity and flexibility. In addition, the flexible sensor board 110 also can be Flexure Print Circuit (FPC), and the insulating material of which (e.g., the dielectric layer 115) can be polyimide (PI), thermoplastic polyimide (TPI), polyethylene terephthalate (PET), or polyethylene (PE), but not limited to.

The support board 150 can include a sheet having flexibility and extensibility, which can be made of metallic material, such as stainless steel or red copper. The support board 150 also can be circuit board, for example, FPC, but not limited to. The support board 150 can be bent. For example, the support board 150 can be bent into a U-shape. In addition, the support board 150 can even be a chassis for an electronic device or a wearable device. The adhesive layer 140 can be adhesive, which can be a light-curing adhesive or a heat-curing adhesive.

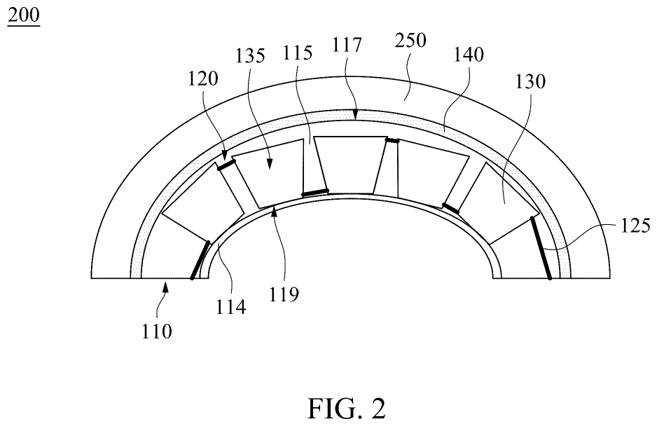

FIG. 2 is a cross-section schematic diagram of a pressure sensor 200 bending according to another embodiment of the present disclosure. Referring to FIG. 2, the pressure sensor 200 is similar with the abovementioned pressure sensor 100, but the cross-sectional structure is partially different. The difference is in the surface (not labeled) of the flexible sensor board 110 covered by the support board 250. Specifically, the second surface 119 of the flexible sensor board 110 of FIG. 1 is covered by the support board 150, however the first surface 117 of the flexible sensor board 110 of FIG. 2 is covered by the support board 250. Under the condition of coaxial and equal perimeter of the flexible sensor board 110, the perimeter of the support board 250 of FIG. 2 is larger than the perimeter of the support board 150 of FIG. 1.

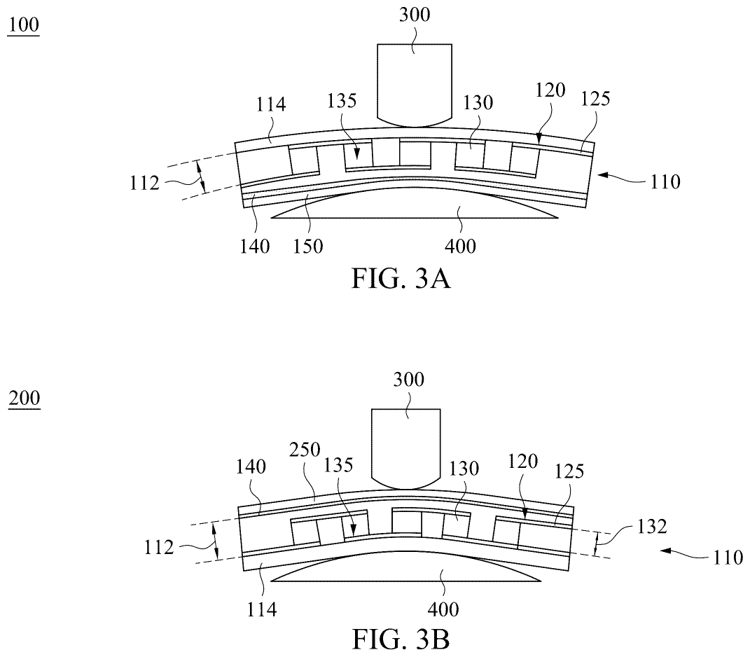

FIG. 3A is a cross-section schematic diagram of the pressure sensor 100 measuring the tested sample 400 according to FIG. 1. Referring to FIG. 3A, the support board 150 of the pressure sensor 100 contacts the tested sample 400. The tested sample 400 has a curved surface, and a pressure application 300 is placed on the above of the flexible sensor board 110 in which the pressure is applied for measurement.

FIG. 3B is a cross-section schematic diagram of the pressure sensor 200 measuring the tested sample 400 according to FIG. 2. Referring to FIG. 3B, the flexible sensor board 110 of the pressure sensor 200 contacts the tested sample 400. The tested sample 400 has the curved surface, for example, an outer convex surface (not labeled), and the pressure application 300 is placed on the above of the support board 250 in which the pressure is applied for measurement.

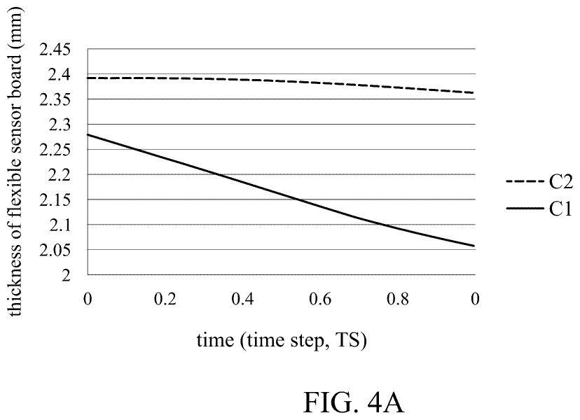

FIG. 4A is a plot of time versus deformation of the thickness 112 of the flexible sensor board 110 at the constant pressure according to FIG. 3A and FIG. 3B. In FIG. 4A, the vertical axis represents the thickness 112 of the flexible sensor board 110 (labeled in FIG. 3A and FIG. 3B), and the horizontal axis represents time. Curve C1 represents the pressure sensor 100 of FIG. 3A and curve C2 represents the pressure sensor 200 of FIG. 3B. As seen in FIG. 4A, the pressure sensor 100 (i.e., curve C1) and the pressure sensor 200 (i.e., curve C2) are under the constant pressure, over time, the thickness 112 of the flexible sensor board 110 showing on a downward trend. And time and the thicknesses 112 of the flexible sensor board 110 are negatively correlated. When the time has passed to the time step (TS) is 1, the amount of deformation of the thicknesses 112 of the flexible sensor board 110 is recorded in Table 1.

The following Table 1 shows the experimental data of two embodiments of FIG. 4A in order to illustrate the efficacy and advantages of the present disclosure. However, it is not intended to limit the present disclosure, and those PHOSITA of the present disclosure may make various changes and embellishments without departing from the spirit and scope of the present disclosure.

TABLE 1

| Pressure | Pressure | Pressure |
|---|---|---|
| deformation | sensor 100 | sensor 200 |
| assessment | (curve C1) | (curve C2) |
| Amount of | 0.2227 | 0.0296 |
| deformation (mm) | | |

As shown in Table 1, the amount of deformation of curve C1 (as shown in FIG. 3A, that is, the pressure application 300 is placed on the above of the flexible sensor board 110 of the pressure sensor 100) is 0.2227 mm, and paired with the value of 1 for the time step of FIG. 4A, where the resulting slope is 0.2227. The amount of deformation of the curve C2 (as shown in FIG. 3B, that is, the pressure application 300 is placed on the above of the support board 250 of the pressure sensor 200) is 0.0296 mm, and paired with a value of 1 for the time step of FIG. 4A, where the resulting slope is 0.0296.

From this, it is known that the amount of deformation of the curve C1 (i.e., the pressure application 300 is placed on above of the flexible sensor board 110), under a constant pressure over time, is greater than the amount of deformation of the curve C2 (i.e., the pressure application 300 is placed on above of the support board 250).

FIG. 4B is a plot of time versus deformation of the heights 132 of the piezoelectric sensing blocks 130 at the constant pressure according to FIG. 3B. In FIG. 4B, the vertical axis represents the heights 132 of the piezoelectric sensing blocks 130 (e.g., the height 132 shown in FIG. 3B), and the horizontal axis represents time. Curve C3 is the average amount of deformation of the height 132 of the piezoelectric sensing blocks 130 over time under the constant pressure, when the pressure application 300 is placed on the above of the support board 250. There are 3 holes 135 in the dielectric layer 115 of the flexible sensor board 110, i.e., there are 3 piezoelectric sensing blocks 130 in the flexible sensor board 110. The difference with curve C3 is that curve C4 has 2 piezoelectric sensing blocks 130 of the flexible sensor board 110, however, curve C5 has 1 piezoelectric sensing blocks 130 of the flexible sensor board 110.

As seen in FIG. 4B, under the constant pressure, over time, the heights 132 of the piezoelectric sensing blocks 130 shows on a downward trend, and time and the heights 132 of the piezoelectric sensing blocks 130 are negatively correlated. As can be seen from FIG. 4B, the curve C5 is in the condition that there is one hole 135 in dielectric layer 115 of the flexible sensor board 110, and the pressure application 300 is placed on the above of the support board 250. Curve C5 deforms the height 132 of the piezoelectric sensing block 130 at a constant pressure over time with a slower deformation trend than curve C4 and curve C3.

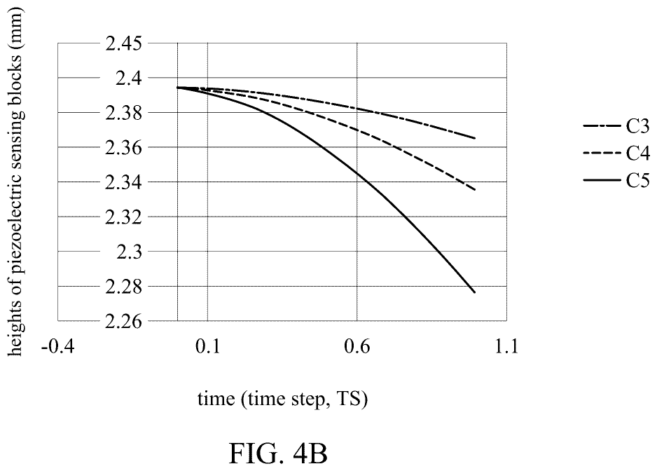

FIG. 5A to FIG. 5D are cross-section schematic diagrams of a generic step of a method of manufacturing the pressure sensor 100 or the pressure sensor 200 of at least one embodiment of the present disclosure. Referring to FIG. 5A, the circuit layer 120 is placed on a surface 116 of the dielectric layer 115, and the circuit layer 120 includes traces 125. Referring to FIG. 5B, FIG. 5B is an alternative embodiment of the circuit layer 120 placed on the surface 116 of the dielectric layer 115. These holes 135 are formed within the dielectric layer 115 and extend though the surface 116 of the dielectric layer 115 to stop at the circuit layer 120.

Referring to FIG. 5C, FIG. 5C is a cross-section schematic diagram continuing the method of manufacturing of FIG. 5B. The method of placing these piezoelectric sensing blocks 130 in the dielectric layer 115 includes filling these holes 135 with these piezoelectric materials (not labeled) respectively, and curing these piezoelectric materials (not labeled) to form the piezoelectric sensing blocks 130. Referring to FIG. 5D, FIG. 5D is another example of the circuit layers manufactured in the dielectric layer 115 and placing these piezoelectric sensing blocks 130 in the dielectric layer 115.

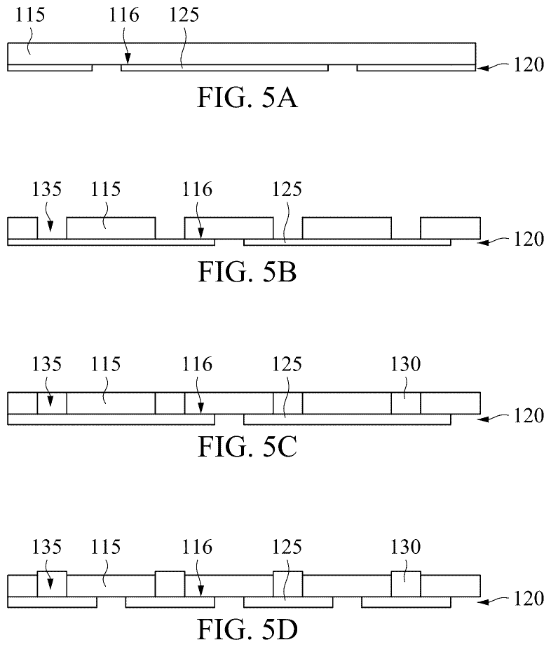

FIG. 6A to FIG. 6B are cross-section schematic diagrams continuing the method of manufacturing of FIG. 5A to FIG. 5D. Referring to FIG. 6A, FIG. 6A depicts a formation of a flexible sensor board 510 from FIG. 5A, FIG. 5D, and FIG. 5C sequentially by squeezing from top to bottom to form one of the embodiments of the present disclosure. Thereafter, the adhesive layer 140 is attached to the second surface 119 of the flexible sensor board 510.

Referring to FIG. 6B, FIG. 6B is continuing of FIG. 6A where the adhesive layer 140 is attached between the flexible sensor board 510 and the support board 150. The piezoelectric sensing blocks 130 of the flexible sensor board 510 also include resistors 160. The resistor 160 is formed by the trace 125 embed in the middle of the dielectric layer 115 of FIG. 6A.

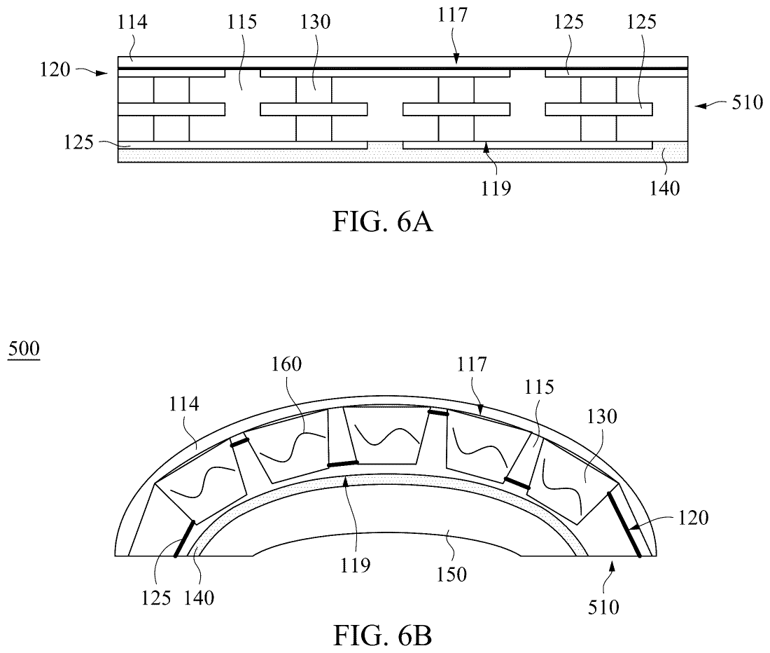

FIG. 7A to FIG. 7B are cross-section schematic diagrams continuing the method of manufacturing of FIG. 5A to FIG. 5D. Referring to FIG. 7A, FIG. 7A depicts a formation of a flexible sensor board 610 from FIG. 5A to FIG. 5D sequentially by squeezing from top to bottom to form one of the embodiments of the present disclosure. Thereafter, the adhesive layer 140 is attached to the first surface 117 of the flexible sensor board 610.

Referring to FIG. 7B, FIG. 7B is continuing of FIG. 7A where the adhesive layer 140 is attached between the flexible sensor board 610 and the support board 250. The piezoelectric sensing blocks 130 of the flexible sensor board 610 also include alloys 170. The alloy 170 is made by pressing. Due to the presence of the alloys 170, the bonding of the piezoelectric sensing blocks 130 to the traces 125 are increased. It also thus reduces the requirement for the holes (not labeled), which is beneficial for the lifetime of the pressure sensor 600.

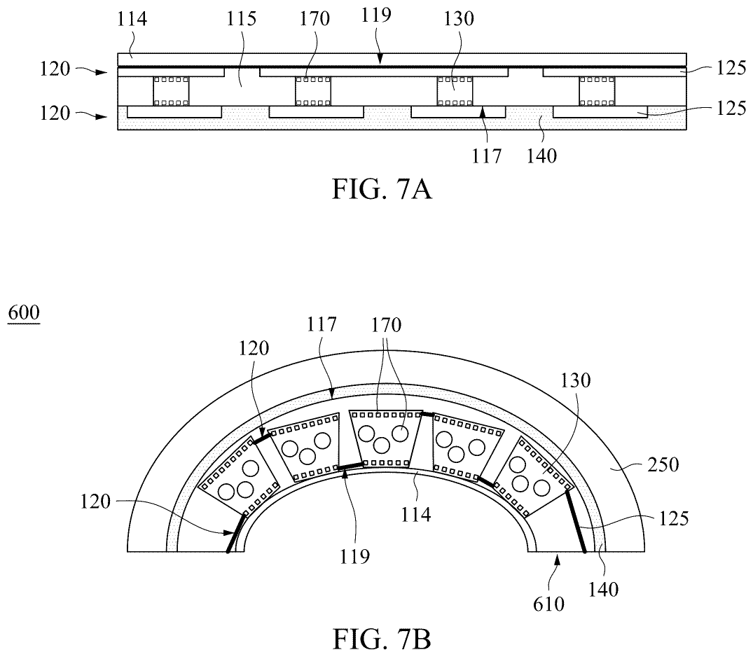

FIG. 8A to FIG. 8B are cross-section schematic diagrams of a method of manufacturing the pressure sensor (not labeled) of at least one embodiment of the present disclosure. Referring to FIG. 8A, these holes 135 in the dielectric layer 115 are filled with these piezoelectric materials (not labeled) using a printing method respectively, and these piezoelectric materials (not labeled) is baked and cured to form these piezoelectric sensing blocks 130. Thereafter, electrically connecting these piezoelectric sensing blocks 130 with the two circuit layers 120 forms the flexible sensor board 710 of one of the embodiments of the present disclosure.

Referring to FIG. 8B, FIG. 8B is continuing of FIG. 8A in which these holes 135 in the dielectric layer 115 are plated against the surface (not labeled) of the piezoelectric sensing blocks 130 within these holes 135 to form a plating layer 180. This is one embodiment of the flexible sensor board 810 of the present disclosure. Compared to the flexible sensor board 710 of FIG. 8A, this flexible sensor board 810 may enhance the structural stability of the flexible sensor board 810.

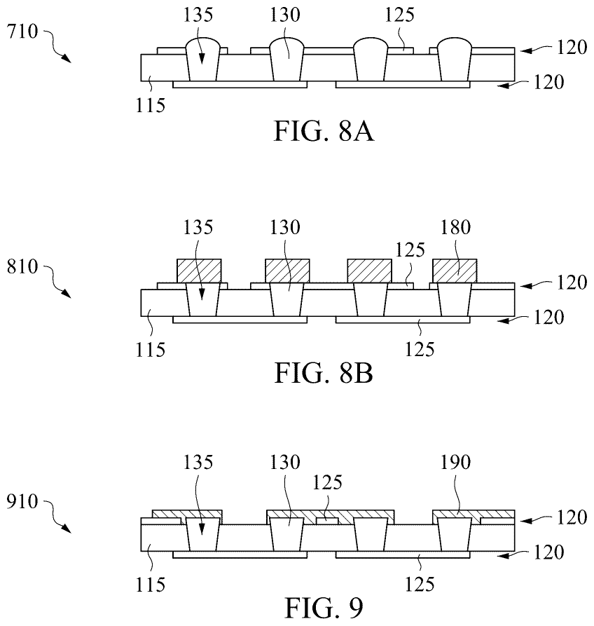

FIG. 9 is a cross-section schematic diagram of a method of manufacturing the pressure sensor (not labeled) of at least one embodiment of the present disclosure. Referring to FIG. 9, these holes 135 in the dielectric layer 115 are filled with these piezoelectric materials (not labeled) using hole plugging and baking to cure the piezoelectric material (not labeled) to form the piezoelectric sensing blocks 130 respectively. These piezoelectric sensing blocks 130 is electrically connected to the two circuit layers 120. Thereafter, silver pastes are printed against the surface (not labeled) of the piezoelectric sensing blocks 130 inside these holes 135 in the dielectric layer 115 to form a silver paste layer 190.

FIG. 9 illustrates a flexible sensor board 910 of one embodiment of the present disclosure. Compared to the flexible sensor board 810 of FIG. 8B, the flexible sensor board 910 has no plating layer 180 of FIG. 8B, and the pressure sensor (not labeled) based on this flexible sensor board 910 is able to maintain a uniform force to improve the measurement accuracy.

In summary, in the pressure sensor 100 or pressure sensor 200 of at least one embodiment of the present disclosure, utilizing the abovementioned flexible sensor board 110 not only to be suitable for different surfaces (not labeled) of the tested samples, such as curved surfaces, but also to uniformly distribute the strain to improve the accuracy of the measurement.

Although the present application has been disclosed in various embodiments as above, it is not intended to limit the present application. The components of several embodiments are summarized above so that those with PHOSITA to which the present disclosure belongs can more easily understand the opinion of the embodiments. Those PHOSITA of the present disclosure should understand that they can design or modify other processes and structures based on the embodiments of the present disclosure to achieve the same purposes and/or advantages as the embodiments introduced here. Those PHOSITA to which the present disclosure belongs should also understand that such equivalent processes and structures do not deviate from the spirit and scope of the present disclosure, and they can be used, various changes, substitutions and substitutions are made, without departing from the spirit and scope of the present disclosure. So the protection scope of this application shall be determined by the appended patent application scope.

What is claimed is:

1. A pressure sensor, comprising:
a flexible sensor board, comprising:
a dielectric layer, having a first surface and a second surface opposite to the first surface;
two circuit layers, placing on the first surface and the second surface of the dielectric layer respectively; and
a plurality of piezoelectric sensing blocks, placing in the dielectric layer and electrically connecting with the two circuit layers.

2. The pressure sensor of claim 1, further comprising:
a support board, having a curved surface, covering one of the first surface and the second surface of the flexible sensor board; and
an adhesive layer, attaching between the flexible sensor board and the support board.

3. The pressure sensor of claim 2, wherein the curved surface of the support board is a concave surface.

4. The pressure sensor of claim 2, wherein the curved surface of the support board is a convex surface.

5. The pressure sensor of claim 1, wherein each of the two circuit layers comprises a plurality of traces and at least one of these traces is electrically connected two of these piezoelectric sensing blocks.

6. The pressure sensor of claim 2, wherein the support board is flexure print circuit or plate of steel.

7. The pressure sensor of claim 1, wherein these piezoelectric sensing blocks comprise a plurality of resistors.

8. The pressure sensor of claim 1, wherein these piezoelectric sensing blocks comprise a plurality of alloys.

9. A method of manufacturing of a pressure sensor, comprising:
providing a dielectric layer which has a first surface and a second surface opposite to the first surface;
placing two circuit layers on the first surface and the second surface of the dielectric layer respectively;
placing a plurality of piezoelectric sensing blocks in dielectric layer; and
electrically connecting these piezoelectric sensing blocks with the two circuit layers.

10. The method of manufacturing of the pressure sensor of claim 9, further comprising:
covering a support board on one of the first surface and the second surface from the dielectric layer; and
attaching an adhesive layer between the dielectric layer and the support board.

11. The method of manufacturing of the pressure sensor of claim 9, wherein the method of electrically connecting the piezoelectric sensing blocks with the two circuit layers comprises plating or printing a surface of these piezoelectric sensing blocks.

12. The method of manufacturing of the pressure sensor of claim 9, wherein the method of placing these piezoelectric sensing blocks in the dielectric layer comprises:
forming a plurality of holes, wherein each of these holes extends from the first surface to the second surface;
filling these holes with a plurality of piezoelectric materials respectively; and
curing these of piezoelectric materials.

13. The method of manufacturing of the pressure sensor of claim 9, wherein the method a formation of a flexible sensor board is from the dielectric layer having these piezoelectric sensing blocks and the two circuit layers by squeezing.

14. The method of manufacturing of the pressure sensor of claim 13, wherein amount of layers of the flexible sensor board is one or more two.

15. The method of manufacturing of the pressure sensor of claim 9, wherein a resistor is formed by embedding a plurality of traces in the dielectric layer
